(19) United States
(12) Patent Application Publication
(10) Pub. No.: US 2025/0189999 A1
(43) Pub. Date: Jun. 12, 2025

(54) VAPORIZATION DEVICE, MATERIAL STATE DETERMINATION DEVICE, MATERIAL STATE DETERMINATION METHOD FOR VAPORIZATION DEVICE, AND MATERIAL STATE DETERMINATION PROGRAM FOR VAPORIZATION DEVICE

(71) Applicant: HORIBA STEC, Co., Ltd., Kyoto-shi (JP)

(72) Inventors: Toshihiro IKEYAMA, Kyoto-shi (JP); Takao WATANABE, Kyoto-shi (JP)

(21) Appl. No.: 18/956,405

(22) Filed: Nov. 22, 2024

(30) Foreign Application Priority Data
Dec. 6, 2023 (JP) 2023-205898

(51) Int. Cl. G05D 7/06; G01F 1/68; G01N 11/02

(52) U.S. Cl. CPC G05D 7/0617; G01F 1/68; G01N 11/02

(57) ABSTRACT

A vaporizer that vaporizes a material, a flow rate control device including a flow rate sensor that measures a flow rate of a material gas generated by the vaporizer, and a determination unit that determines that the material gas has returned to a state before the vaporization on the basis of a transient response of the flow rate measured by the flow rate sensor are included.

### CROSS-REFERENCE TO RELATED APPLICATION

The present application claims priority to Japanese Patent Application No. 2023-205898 filed Dec. 6, 2023, entitled “VAPORIZATION DEVICE, MATERIAL STATE DETERMINATION DEVICE, MATERIAL STATE DETERMINATION METHOD FOR VAPORIZATION DEVICE, AND MATERIAL STATE DETERMINATION PROGRAM FOR VAPORIZATION DEVICE” which is incorporated herein by reference in its entirety.

### BACKGROUND OF THE INVENTION

### Technical Field

The present invention relates to a vaporization device, a material state determination device, a material state determination method for a vaporization device, and a material state determination program for a vaporization device.

### Description of the Related Art

As this type of vaporization device, for example, there is a vaporization device that generates a material gas by heating and vaporizing a liquid material or a solid material used for semiconductor manufacturing and that supplies the material gas to a semiconductor manufacturing chamber or the like. As disclosed in JP 5548292 B2, for example, this vaporization device includes a vaporization device that heats and vaporizes a liquid material or a solid material and a flow rate control device (so-called mass flow controller) that controls a flow rate of a material gas generated by the vaporization device.

In this vaporization device, when vaporization failure such as returning of the generated material gas to a state before the vaporization occurs, a product defect can occur in semiconductor manufacturing, and therefore the flow rate control device, piping from the vaporization device to the flow rate control device, and the like are heated by a heater or the like.

In this vaporization device, however, although the flow rate control device and the piping thereto are heated, the material gas might return to the state before the vaporization. For this reason, when a measured flow rate measured by the flow rate control device continues to deviate from a set flow rate of the flow rate control device for a predetermined time, it is conventionally determined that there is a possibility of vaporization failure such as returning of the material gas to the state before the vaporization.

In the detection method described above, however, since other factors such as control failure of the flow rate control device are also involved, it is not possible to determine only the possibility of vaporization failure. Moreover, it is necessary for the deviation to continue for the predetermined time, and detection of the returning to the state before the vaporization is undesirably delayed. Furthermore, for example, in a thin film forming technology such as an atomic layer deposition (ALD) method, since a purge step is performed during a film forming step, the measured flow rate fluctuates, and it becomes difficult to detect the returning to the state before the vaporization.

### PRIOR ART DOCUMENT

### Patent Document

JP 5548292 B2

### SUMMARY OF THE INVENTION

The present invention, therefore, has been made to solve the above-described problems, and an object thereof is to accurately determine that a material gas has returned to a state before vaporization.

That is, a vaporization device in the present invention includes a vaporizer that vaporizes a material, a flow rate control device including a flow rate sensor that measures a flow rate of a material gas generated by the vaporizer, and a determination unit that determines that the material gas has returned to a state before the vaporization on a basis of transient response data that is flow rate data at a time of a transient response measured by the flow rate sensor.

With this vaporization device, since it is determined that the material gas has returned to the state before the vaporization on the basis of the transient response data measured by the flow rate sensor, it is possible to accurately determine that the material gas has returned to the state before the vaporization. Specifically, a behavior (for example, a waveform change) due to returning of the material gas to the state before the vaporization is likely to appear in the transient response data, and it is possible to accurately determine that the material gas has returned to the state before the vaporization using the behavior. Furthermore, in the present invention, an additional sensor for detecting the returning to the state before the vaporization is not essential, and the device can be downsized.

It is desirable that the determination unit determine that the material gas has returned to the state before the vaporization on a basis of differential data obtained by differentiating the transient response data.

With this configuration, by differentiating the transient response data, it is possible to easily grasp a behavior (for example, a waveform change) due to the returning to the state before the vaporization included in the transient response data, and it is possible to accurately determine that the material gas has returned to the state before the vaporization.

It is conceivable that the behavior (for example, the waveform change) due to the returning to the state before the vaporization included in the transient response data appears as an inflection point in the transient response data. It is therefore desirable that the determination unit determine that the material gas has returned to the state before the vaporization on a basis of presence or absence of an inflection point in the transient response data.

Since one inflection point appears due to a change caused by rising or a change due to falling at a time of a transient response, in order to capture an inflection point indicating a behavior due to liquefaction, not a change due to rising or a change due to falling, it is desirable that the determination unit determine that the material gas has returned to the state before the vaporization when there are two or more inflection points in the transient response data.

As a specific embodiment of determining that the material gas has returned to the state before the vaporization, it is desirable that the determination unit determine that the material gas has returned to the state before the vaporization on a basis of the transient response data at a time of falling.

In order to more accurately determine that the material gas has returned to the state before the vaporization, it is desirable that the determination unit remove noise from the transient response data, and determine that the material gas has returned to the state before the vaporization on a basis of the transient response data from which the noise has been removed.

As a specific embodiment when it has been determined that the material gas has returned to the state before the vaporization, it is desirable that, when the determination unit determines that the material gas has returned to the state before the vaporization, a heating temperature of the vaporizer or piping be changed, a temperature control area be changed, or a vaporization operation be stopped. Alternatively, a heating temperature of piping in the vaporization device may be changed or a temperature control area in the vaporization device may be changed by checking whether there is a cold spot or the like.

When the flow rate sensor is of a thermal type, the behavior due to the returning of the material gas to the state before the vaporization is likely to appear, and it is possible to more accurately determine that the material gas has returned to the state before the vaporization.

In addition, a material state determination device in the present invention is a material state determination device used in a vaporization device including a vaporizer that vaporizes a material and a flow rate control device including a flow rate sensor that measures a flow rate of a material gas generated by the vaporizer, the material state determination device including a determination unit that determines that the material gas has returned to a state before the vaporization on a basis of transient response data that is flow rate data at a time of a transient response measured by the flow rate sensor.

In addition, a material state determination method for a vaporization device in the present invention is a material state determination method for a vaporization device including a vaporizer that vaporizes a material and a flow rate control device including a flow rate sensor that measures a flow rate of a material gas generated by the vaporizer, the material state determination method including determining that the material gas has returned to a state before the vaporization on a basis of transient response data that is flow rate data at a time of a transient response measured by the flow rate sensor.

Furthermore, a material state determination program for a vaporization device in the present invention is a material state determination program for a vaporization device including a vaporizer that vaporizes a material and a flow rate control device including a flow rate sensor that measures a flow rate of a material gas generated by the vaporizer, the material state determination program causing a computer to function as a determination unit that determines that the material gas has returned to a state before the vaporization on a basis of transient response data that is flow rate data at a time of a transient response measured by the flow rate sensor.

As described above, according to the present invention, since it is determined that a material gas has returned to a state before vaporization on the basis of transient response data obtained by a flow rate sensor, it is possible to accurately determine that the material gas has returned to the state before the vaporization.

### BRIEF DESCRIPTION OF THE DRAWINGS

FIG. 1 is a diagram schematically illustrating a configuration of a vaporization device according to an embodiment of the present invention; and

FIG. 2(a) illustrates transient response data in a normal state without liquefaction and differential data thereof, and FIG. 2(b) illustrates transient response data in an abnormal state with liquefaction and differential data thereof.

### DETAILED DESCRIPTION

An embodiment of a vaporization device in the present invention will be described hereinafter with reference to the drawings.

Note that the drawings shown below are all schematic drawings including appropriate omission and exaggeration for easy understanding. The same components are given the same reference numerals, and description thereof is omitted as appropriate.

### Configuration of Vaporization Device

A vaporization device 100 according to the present embodiment is for, for example, heating and vaporizing a liquid material used for semiconductor manufacturing to generate a material gas and supplying the material gas to a semiconductor manufacturing chamber or the like. Note that the vaporization device 100 according to the present embodiment vaporizes a liquid material, but may vaporize a solid material, instead.

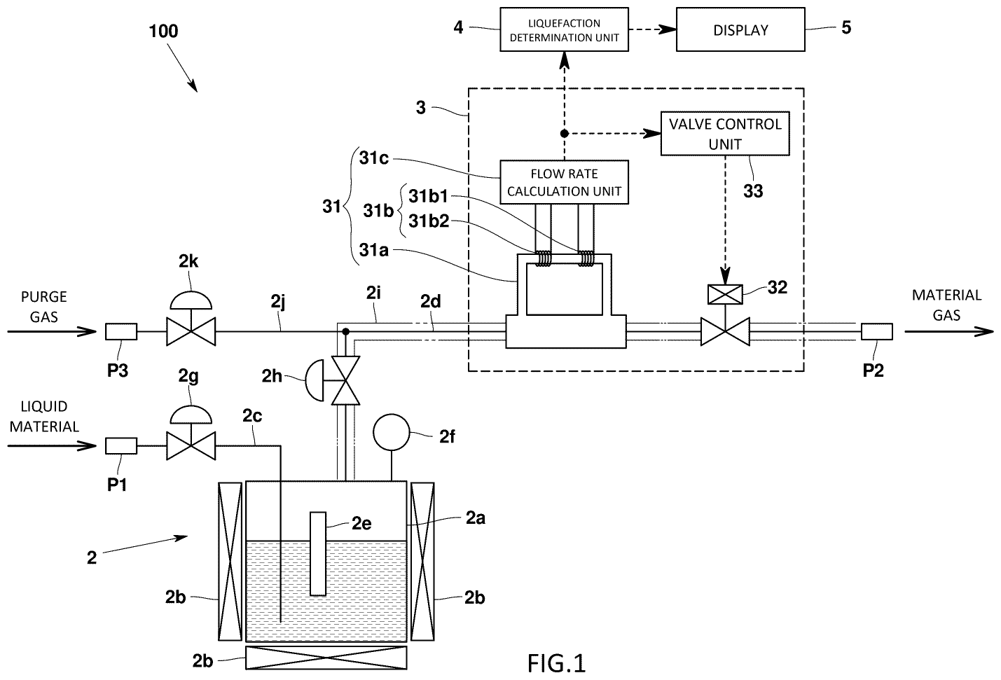

Specifically, as illustrated in FIG. 1, the vaporization device 100 includes a vaporizer 2 that vaporizes a liquid material and a flow rate control device 3 that controls a flow rate of a material gas generated by the vaporizer 2.

The vaporizer 2 is of a baking type (heating type), and includes a tank 2a that stores a liquid material, a heater 2b that heats the tank 2a, an introduction pipe 2c that supplies the liquid material to the tank 2a, and a lead-out pipe 2d that leads out a generated material gas from the tank 2a.

The tank 2a stores a predetermined amount of liquid material, and is formed of, for example, a corrosion resistant metal such as stainless steel. Note that the tank 2a is provided with a liquid amount sensor 2e such as a liquid level sensor in order to maintain the amount of the liquid material within a predetermined range. The tank 2a might also be provided with a pressure sensor 2f that measures pressure inside the tank 2a.

The heater 2b is, for example, a heater or the like, and is disposed in such a way as to surround an inside or an outer peripheral side surface and/or a bottom surface of the tank 2a. In the tank 2a heated by the heater 2b, the liquid material reaches a saturated vapor pressure and vaporizes to generate material gas. A heating temperature to be achieved by the heater 2b is appropriately set in accordance with the liquid material.

The introduction pipe 2c is provided in such a way as to penetrate, for example, an upper wall of the tank 2a, and a lower end thereof extends to vicinity of the bottom surface of the tank 2a. An introduction port P1 for introducing the liquid material is provided at an upstream end of the introduction pipe 2c. Furthermore, a flow rate adjusting valve 2g for adjusting a flow rate of the liquid material supplied to the tank 2a is provided in the introduction pipe 2c outside the tank 2a. A valve opening of the flow rate adjusting valve 2g is controlled on the basis of a detection signal of the liquid amount sensor 2c.

The lead-out pipe 2d is opened in, for example, the upper wall of the tank 2a, and communicates with an internal space of the tank 2a. The material gas generated in the tank 2a then flows into the lead-out pipe 2d and is led out from the tank 2a. A supply port P2 for supplying the material gas to the semiconductor manufacturing chamber or the like is provided at a downstream end of the lead-out pipe 2d. An on-off valve 2h is also provided in the lead-out pipe 2d, and the on-off valve 2h is closed when the material gas is not led out from the tank 2a. The lead-out pipe 2d is heated by a heater 2i to a predetermined temperature from a connection portion of the tank 2a to the supply port P2 so that the material gas is not liquefied.

Furthermore, in the lead-out pipe 2d, a purge gas supply pipe 2j for supplying a purge gas is connected between the on-off valve 2h and the flow rate control device 3, which will be described later. A supply port P3 for supplying the purge gas is provided at an upstream end of the purge gas supply pipe 2j. The purge gas supply pipe 2j is also provided with an on-off valve 2k, and the on-off valve 2k is closed when the purge gas is not supplied.

The flow rate control device 3 is provided in the lead-out pipe 2d and controls the flow rate of the material gas flowing through the lead-out pipe 2d. Specifically, the flow rate control device 3 includes a flow rate sensor 31 that measures the flow rate of the material gas, a fluid control valve 32 provided on an upstream side or a downstream side (here, the downstream side) of the flow rate sensor 31, and a valve control unit 33 that controls the fluid control valve 32 on the basis of a measured flow rate of the flow rate sensor 31.

The flow rate sensor 31 is a thermal flow rate sensor, and includes a sensor pipe 31a through which the material gas flows, a sensing unit 31b that detects physical quantities (for example, currents, voltages, resistances, or the like) related to temperatures on an upstream side and a downstream side of the sensor pipe 31a, and a flow rate calculation unit 31c that calculates the flow rate of the material gas on the basis of a detection signal obtained by the sensing unit 31b.

An upstream end and a downstream end of the sensor pipe 31a are connected to the lead-out pipe 2d to bypass part of the material gas.

The sensing unit 31b uses a thermosensitive resistor whose electric resistance value increases and decreases with temperature change, and includes an upstream sensor 31b1 wound on the upstream side of the sensor pipe 31a in a coil shape and a downstream sensor 31b2 wound on the downstream side of the sensor pipe 31a in a coil shape.

The flow rate calculation unit 31c includes an electric circuit, and includes a control circuit that performs control such that temperatures of the upstream sensor 31bl and the downstream sensor 31b2 are always equal and constant, an amplifier circuit that amplifies an electric signal output from the control circuit, and a conversion circuit that converts the electric signal amplified by the amplifier circuit into a flow rate. Note that the flow rate calculation unit 31c may cause a constant current to flow through the upstream sensor 31bl and the downstream sensor 31b2 using a constant current circuit, and convert a temperature difference between the upstream sensor 31b1 and the downstream sensor 31b2 at that time into a flow rate.

The valve control unit 33 controls the fluid control valve 32 on the basis of the measured flow rate of the material gas calculated by the flow rate calculation unit 31c. Note that the valve control unit 33 is, for example, a so-called computer including a CPU, a memory, A/D and D/A converters, and an input/output unit, and controls the fluid control valve 32 by executing a program stored in the memory and causing various devices to cooperate.

Specifically, the valve control unit 33 performs flow rate feedback control on the opening of the fluid control valve 32 such that a deviation of the measured flow rate calculated by the flow rate calculation unit 31c from the set flow rate set by a user becomes small. The valve control unit 33 is a PID controller that receives the deviation of the measured flow rate from the set flow rate and that outputs a voltage command to be applied to the fluid control valve 32 through PID calculation.

### Liquefaction Determination Function

The vaporization device 100 according to the present embodiment has a function of determining that a material gas has returned to a state before vaporization, that is, a function of determining that the material gas has liquefied. Here, “determining that a material gas has returned to a state before vaporization” means, in a case of a solid material, determining that the material gas has returned to a solid, and, in a case of a liquid material, determining that the material gas has returned to a liquid.

Specifically, the vaporization device 100 includes a liquefaction determination unit 4 that determines that the material gas has liquefied on the basis of transient response data that is flow rate data at a time of a transient response measured by the flow rate sensor 31. Note that the transient response data may be analog data or digital data.

Here, the time of a transient response is a time of falling, and the liquefaction determination unit 4 determines that the material gas has liquefied on the basis of transient response data at the time of falling. Falling (transient response) of the measured flow rate occurs, for example, when the fluid control valve 32 is fully closed with the set flow rate (set value) of the flow rate control device 3 set to zero from a predetermined flow rate (for example, a flow rate larger than zero such as 500 [sccm]).

The liquefaction determination unit 4 may be configured to achieve the function thereof, for example, by storing a liquefaction determination program in a memory of the same computer as the valve control unit 33 described above, or may be configured to achieve the function thereof by storing the liquefaction determination program in a memory of a computer different from that of the valve control unit 33. Note that the liquefaction determination unit 4 may cause the flow rate control device 3 to have the function, or may cause a semiconductor manufacturing apparatus to have the function.

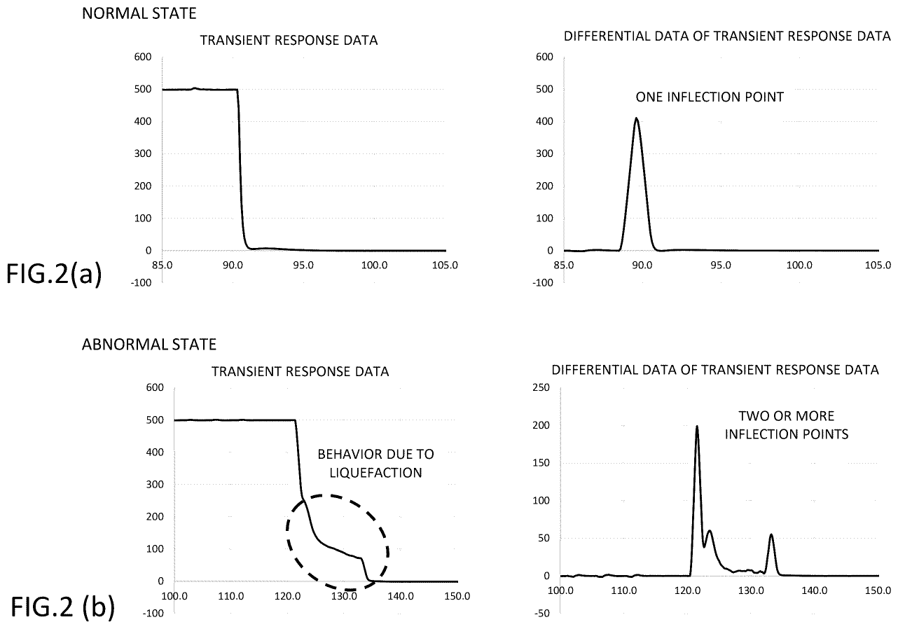

Specifically, as illustrated in FIGS. 2A and 2B, the liquefaction determination unit 4 determines that the material gas has liquefied on the basis of differential data obtained by time-differentiating the transient response data. Specifically, the liquefaction determination unit 4 detects presence or absence of inflection points in the transient response data from the differential data, and determines that the material gas has liquefied on the basis of the presence or absence of the inflection points.

Here, as illustrated in FIG. 2(b), when there are two or more inflection points, the liquefaction determination unit 4 determines that the material gas has liquefied. This is because an inflection point indicating a behavior due to liquefaction, not a change due to falling, is captured in addition to one inflection point due to a change caused, when there is no liquefaction, by the falling at the time of a transient response as illustrated in FIG. 2(a).

Alternatively, the liquefaction determination unit 4 may remove flow rate noise and noise due to disturbance from the transient response data, and determine that the material gas has liquefied on the basis of the transient response data from which the noise has been removed. Here, as a noise removal method, for example, it is conceivable to perform moving average of the transient response data.

Moreover, if the liquefaction determination unit 4 determines that the material gas has liquefied, it is conceivable to notify the user of the liquefaction of the material gas. Specifically, it is conceivable to perform a liquefaction determination display on a display 5 of a computer, and it is also conceivable to notify by sound or light using a notification device provided in a line (site) incorporating the vaporization device 100.

Furthermore, when the liquefaction determination unit 4 determines that the material gas has liquefied, the vaporization device 100 may perform control in such a way as to change (specifically, increase) a heating temperature of the vaporizer 2 or stop a vaporization operation. In addition, whether there is a cold spot may be checked, and a heating temperature of the piping of the vaporization device 100 or a temperature control area of the vaporization device 100 may be changed.

### Effects of Present Embodiment

As described above, with the vaporization device 100 according to the present embodiment, since it is determined that the material gas has liquefied on the basis of the transient response data measured by the flow rate sensor 31, it is possible to accurately determine that the material gas has liquefied. Specifically, a behavior (for example, a waveform change) due to liquefaction of the material gas is likely to appear in the transient response data, and the liquefaction of the material gas can be accurately determined using the behavior due to the liquefaction.

In addition, since the liquefaction determination unit 4 determines that the material gas has liquefied on the basis of differential data obtained by differentiating the transient response data, it is possible to easily grasp a behavior (for example, a waveform change) due to liquefaction included in the transient response data and to accurately determine the liquefaction of the material gas.

Furthermore, in the present embodiment, since the thermal flow rate sensor 31 is used, the behavior due to the liquefaction of the material gas can be easily observed, and the liquefaction of the material gas can be determined more accurately.

### OTHER EMBODIMENTS

For example, a liquefaction determination method employed by the liquefaction determination unit 4 is not limited to the method based on inflection points, and the liquefaction may be determined on the basis of the amount of change in the differential data. The liquefaction can be determined, for example, when the amount of change in the differential data is larger than or equal to a predetermined value, or when the amount of change in the differential data is smaller than the predetermined value and does not become zero within a predetermined time.

Specifically, in order to prevent an erroneous determination due to an operation of a shut-off valve on a vaporization device side or the like at a time of a falling response, a threshold is provided for a differential value of the transient response data at a time of falling, and liquefaction is not determined in a case of a steep response accompanying the operation of the shut-off valve or the like. For example, it is conceivable to determine that the material gas has liquefied when a falling signal is detected, an inflection point is observed in differential data for a predetermined time after the detection, and the differential data is within a predetermined range. Here, the predetermined range is set to an appropriate value depending on film formation conditions of a semiconductor manufacturing process.

It is also conceivable that the liquefaction determination unit 4 determines the liquefaction without differentiating the transient response data. In this case, for example, it is conceivable to compare, through fitting or the like, the transient response data obtained by the flow rate sensor 31 with transient response data (standard data) in a state where liquefaction has not occurred, for example, and determine the liquefaction on the basis of a result of the comparison.

Furthermore, although the flow rate sensor of the above embodiment is of a thermal type, the flow rate sensor may be of a pressure type or of another measurement principle.

Although the vaporization device 100 has the function of determining that the material gas has liquefied in the above embodiment, a device (liquefaction determination device) different from the vaporization device 100 may be used, instead. That is, the liquefaction determination unit 4 may be provided in a device different from the vaporization device 100.

Although the vaporizer in the above embodiment is of a baking type, the vaporizer may be of a bubbling type, in which a carrier gas is introduced into a liquid material and vaporized through bubbling, or of a bubbling type, in which a carrier gas is sprayed onto a solid material and sublimated, instead.

In addition, various modifications and combinations of the embodiments may be made without departing from the gist of the present invention.

### REFERENCE CHARACTERS LIST

100 Vaporization device
2 Vaporizer
3 Flow rate control device
31 Flow rate sensor
4 Liquefaction determination unit (determination unit)

What is claimed is:

1. A vaporization device comprising:
a vaporizer that vaporizes a material;
a flow rate control device including a flow rate sensor that measures a flow rate of a material gas generated by the vaporizer; and
a determination unit that determines that the material gas has returned to a state before the vaporization on a basis of transient response data that is flow rate data at a time of a transient response measured by the flow rate sensor.

2. The vaporization device according to claim 1, wherein
the determination unit determines that the material gas has returned to the state before the vaporization on a basis of differential data obtained by differentiating the transient response data.

3. The vaporization device according to claim 2, wherein
the determination unit determines that the material gas has returned to the state before the vaporization on a basis of presence or absence of an inflection point in the transient response data.

4. The vaporization device according to claim 1, wherein
the determination unit determines that the material gas has returned to the state before the vaporization when there are two or more inflection points in the transient response data.

5. The vaporization device according to claim 1, wherein
the determination unit determines that the material gas has returned to the state before the vaporization on a basis of the transient response data at a time of falling.

6. The vaporization device according to claim 1, wherein
the determination unit removes noise from the transient response data, and determines that the material gas has returned to the state before the vaporization on a basis of the transient response data from which the noise has been removed.

7. The vaporization device according to claim 1, wherein
when the determination unit determines that the material gas has returned to the state before the vaporization, a heating temperature of the vaporizer or piping is changed, a temperature control area is changed, or a vaporization operation is stopped.

8. The vaporization device according to claim 1, wherein the flow rate sensor is a thermal flow rate sensor.

9. A material state determination device that is a liquefaction determination device used in a vaporization device including a vaporizer that vaporizes a material and a flow rate control device including a flow rate sensor that measures a flow rate of a material gas generated by the vaporizer, the material state determination device comprising:
a determination unit that determines that the material gas has returned to a state before the vaporization on a basis of transient response data that is flow rate data at a time of a transient response measured by the flow rate sensor.

10. A material state determination method for a vaporization device including a vaporizer that vaporizes a material and a flow rate control device including a flow rate sensor that measures a flow rate of a material gas generated by the vaporizer, the material state determination method comprising:
determining that the material gas has returned to a state before the vaporization on a basis of transient response data that is flow rate data at a time of a transient response measured by the flow rate sensor.

11. A non-transitory storage medium storing a material state determination program for a vaporization device including a vaporizer that vaporizes a material and a flow rate control device including a flow rate sensor that measures a flow rate of a material gas generated by the vaporizer, the material state determination program being executable by a computer to cause the computer to:
determine that the material gas has returned to a state before the vaporization on a basis of transient response data that is flow rate data at a time of a transient response measured by the flow rate sensor.
